(19) United States
(12) Patent Application Publication
(10) Pub. No.: US 2021/0335939 A1
(43) Pub. Date: Oct. 28, 2021

(54) DISPLAY PANEL, DISPLAY APPARATUS, AND METHOD FOR PREPARING DISPLAY PANEL

(71) Applicants: HEFEI XINSHENG OPTOELECTRONICS TECHNOLOGY CO., LTD., Hefei, Anhui (CN); BOE TECHNOLOGY GROUP CO., LTD., Beijing (CN)

(72) Inventors: Fei LI, Beijing (CN); Xinfeng WU, Beijing (CN); Youyuan HU, Beijing (CN); Xinzhu WANG, Beijing (CN); Huihui LI, Beijing (CN)

(73) Assignees: HEFEI XINSHENG OPTOELECTRONICS TECHNOLOGY CO., LTD., Hefei, Anhui (CN); BOE TECHNOLOGY GROUP CO., LTD., Beijing (CN)

(21) Appl. No.: 17/269,553

(22) PCT Filed: Jun. 15, 2020
(86) PCT No.: PCT/CN2020/096107

§ 371 Date: Feb. 19, 2021

(30) Foreign Application Priority Data
Jun. 20, 2019 (CN) 201910539445.X

(51) Int. Cl. H01L 27/32; H01L 51/56

(52) U.S. Cl. CPC H01L 27/3246; H01L 51/56

(57) ABSTRACT

A display panel, a display apparatus, and a method for preparing the display panel. The display panel includes: a substrate; an anode layer on the substrate; a pixel definition layer on the substrate, wherein the pixel definition layer includes an opening to at least partially expose the anode layer; a light-emitting layer in the opening of the pixel definition layer and on the anode layer; and a reflection layer on a sidewall of the opening of the pixel definition layer to reflect light emitted from the light-emitting layer.

The present disclosure claims priority of Chinese Patent Application No. 201910539445.X filed on Jun. 20, 2019 and entitled “display panel, display apparatus and method for preparing display panel”, and the entire content disclosed by the Chinese patent application is incorporated herein by reference as part of the present disclosure.

### TECHNICAL FIELD

The present disclosure relates to a display panel, a display apparatus and a preparation method of the display panel.

### BACKGROUND

At present, the increasing demand for display apparatuses has spawned various display apparatuses, such as liquid crystal displays, plasma displays, organic light-emitting displays, and so on. Organic light emitting diode (OLED) display apparatus is a self-luminous display apparatus, and has the advantages such as wide viewing angle, high contrast, low power consumption and fast response time, and becomes increasingly favorable in the market.

### SUMMARY

At least an embodiment of the present disclosure provides a display panel, comprising: a substrate; an anode layer on the substrate; a pixel definition layer on the substrate, wherein the pixel definition layer comprises an opening to at least partially expose the anode layer; a light-emitting layer in the opening of the pixel definition layer and on the anode layer; and a reflection layer on a sidewall of the opening of the pixel definition layer to reflect light emitted from the light-emitting layer.

In the display panel of at least an example, the pixel definition layer includes a first sub-pixel definition layer and a second sub-pixel definition layer; the first sub-pixel definition layer is on the substrate and comprises a first opening at least partially exposing the anode layer, the second sub-pixel definition layer is on a side of the first sub-pixel definition layer away from the substrate and comprises a second opening at least partially exposing the anode layer; an orthographic projection of the second opening on the substrate is located within an orthographic projection of the first opening on the substrate, and corresponds to the opening of the pixel definition layer; the reflection layer is located between a sidewall of the first opening of the first sub-pixel definition layer and a sidewall of the second opening of the second sub-pixel definition layer.

In the display panel of at least an example, the light-emitting layer is on the pixel definition layer and the anode layer.

In the display panel of at least an example, the pixel definition layer is also at least partially formed on a surface of the anode layer on a side away from the substrate.

In the display panel of at least an example, wherein a length of the reflection layer ranges from 1.6 μm to 2.3 μm; a width of the reflection layer ranges from 0.1 μm to 1 μm, and a direction of the width is parallel to a direction of the substrate.

In the display panel of at least an example, a material of the reflection layer comprises any one selected from the group consisting of Al, Cu, Ag, Al₂O₃ and ZnO.

In the display panel of at least an example, an included angle between the reflection layer and the anode layer ranges from 60° to 80°.

In at least an example, the display panel further comprises a cathode layer, wherein the cathode layer is on a side of the light-emitting layer away from the substrate.

In at least an example, the display panel further comprises a package substrate or a package layer, wherein the package substrate or the package layer is on a side of the cathode layer away from the substrate.

At least an embodiment of the present disclosure provides a display apparatus, comprising a display panel according any one of the above embodiments.

At least an embodiment of the present disclosure provides a preparation method of a display panel, comprising: providing a substrate; forming an anode layer on the substrate; forming a pixel definition layer on the substrate, wherein the pixel definition layer comprises an opening to at least partially expose the anode layer; forming a reflection layer on a sidewall of the opening of the pixel definition layer; and forming a light-emitting layer in the opening of the pixel definition layer and on the anode layer.

In the preparation method of at least an example, the forming the pixel definition layer on the substrate, comprises: forming a first sub-pixel definition layer on the substrate, wherein the first sub-pixel definition layer comprises a first opening at least partially exposing the anode layer; and forming a second sub-pixel definition layer on a side of the first sub-pixel definition layer away from the substrate; the second sub-pixel definition layer comprises a second opening at least partially exposing the anode layer, and a orthographic projection of the second opening on the substrate is located within a orthographic projection of the first opening on the substrate and corresponds to the opening of the pixel definition layer.

In the preparation method of at least an example, the forming the reflection layer on the sidewall of the opening of the pixel definition layer, comprises: forming the reflection layer on a sidewall of the first opening of the first sub-pixel definition layer, wherein the reflection layer is located between the sidewall of the first opening of the first sub-pixel definition layer and a sidewall of the second opening of the second sub-pixel definition layer.

In the preparation method of at least an example, the light-emitting layer is on the pixel definition layer and the anode layer.

In the preparation method of at least an example, the pixel definition layer is also at least partially formed on a surface of the anode layer on a side away from the substrate.

In the preparation method of at least an example, a length of the reflection layer ranges from 1.6 μm to 2.3 μm; a width of the reflection layer ranges from 0.1 μm to 1 μm, and a direction of the width is parallel to a direction of the substrate.

In the preparation method of at least an example, a material of the reflection layer comprises any one selected from the group consisting of Al, Cu, Ag, Al₂O₃ and ZnO.

In the preparation method of at least an example, an included angle between the reflection layer and the anode layer ranges from 60° to 80°.

In at least an example, the preparation method further comprises: forming a cathode layer on a side of the light-emitting layer away from the substrate.

In at least an example, the preparation method further comprises: providing a package substrate or a package layer on a side of the cathode layer away from the substrate.

### BRIEF DESCRIPTION OF THE DRAWINGS

In order to explain the technical solutions of the embodiments of the present disclosure more clearly, the drawings of the embodiments will be briefly introduced below. Obviously, the drawings in the following description only relate to some embodiments of the present disclosure, which does not limit the present disclosure.

FIG. 1A and FIG. 1B illustrate structural schematic diagrams of a display panel according to at least one embodiment of the present disclosure, and FIG. 1A is a cross-sectional view along line AA in FIG. 1B;

FIG. 2 illustrates a schematic structural diagram of a display panel according to another embodiment of the present disclosure;

FIG. 3 illustrates a schematic structural diagram of a display panel according to another embodiment of the present disclosure;

FIG. 4 illustrates a schematic structural diagram of a display apparatus according to another embodiment of the present disclosure;

FIG. 5 illustrates a flowchart of a preparation method of a display panel according to at least one embodiment of the present disclosure; and

FIG. 6 illustrates a flowchart of a preparation process of a pixel definition layer according to at least one embodiment of the present disclosure.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present application for disclosure, are not intended to indicate any sequence, amount or importance, but distinguish various components. Also, the terms such as “a,” “an,” etc., are not intended to limit the amount, but indicate the existence of at least one. The terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “On,” “under,” “right,” “left” and the like are only used to indicate relative position relationship, and when the position of the object which is described is changed, the relative position relationship may be changed accordingly.

In an organic light emitting diode top emission display apparatus, the light loss is large and the luminous efficiency is low; in addition, an organic light emitting diode (OLED) display apparatus still suffers color shift depending on viewing angle. In an OLED display apparatus, an OLED formed on a substrate includes an anode, a light-emitting layer and a cathode. For example, the OLED is formed in an opening of a pixel definition layer, only a small part of light emitted from the light-emitting layer is output for display, and rest most of the light is emitted to the sides of the opening of the pixel definition layer and lost, and OLED display apparatus has a problem of color shift depending on viewing angle.

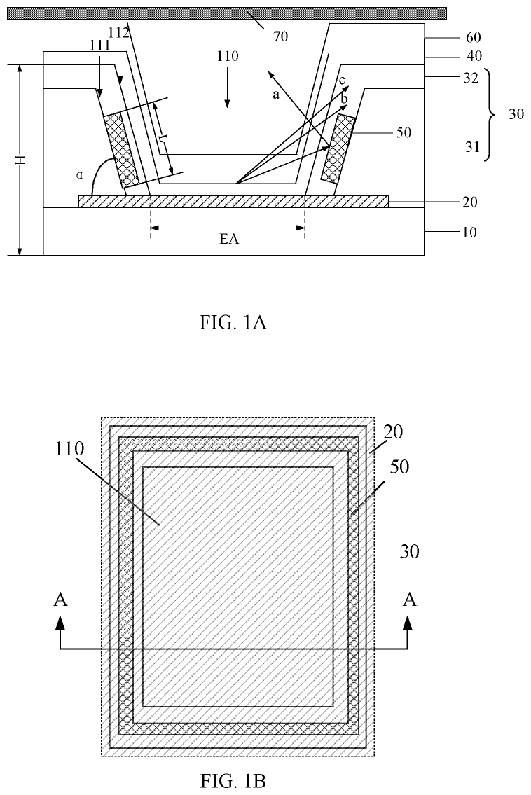

Referring to FIG. 1A and FIG. 1B, at least one embodiment of the present disclosure provides a display panel. FIG. 1A is a cross-sectional view along line AA in FIG. 1B, and corresponds to one pixel unit; only part of a layer structure is shown in FIG. 1B.

The display panel includes a substrate 10 and a light-emitting element formed on the substrate 10; for example, the light-emitting element may be an organic light-emitting diode (OLED) or a quantum dot light-emitting diode (QLED), and the present disclosure does not limit the type of the light-emitting element. For example, an OLED and a QLED may have basically the same structure, and the difference lies in the material used in the light-emitting layer. The OLED uses an organic light-emitting material, while the QLED uses a quantum dot light-emitting material.

For example, the light-emitting element includes an anode layer 20, a light-emitting layer 40, and a cathode layer 60 that are provided on a substrate 10. The display panel further includes a pixel definition layer 30 on the substrate, and an opening 110 is formed in the pixel definition layer 30, and the opening 110 at least partially exposes the anode layer 20. The light-emitting layer 40 is formed at least in the opening 110 of the pixel definition layer 30 and on the anode layer 20. For example, the light-emitting layer 40 may be continuously formed on the pixel definition layer 30 and in the opening 110 of the pixel definition layer 30, thus forming on the anode layer 20 exposed by the opening 110 of the pixel definition layer 30, or the light-emitting layer may be formed only in the opening 110 but not formed on the top surface of the pixel definition layer 30, but may be formed on at least part of the sidewall of the opening 110; the cathode layer 60 is formed on the light-emitting layer 40, and correspondingly may also be continuously formed on the pixel definition layer 30 and in the opening 110 of the pixel definition layer 30. Inside the sidewall of the opening 110 of the pixel definition layer 30, a reflection layer 50 is provided adjacent to the light-emitting layer 40 to reflect light emitted by the light-emitting layer 40.

In the example shown in FIG. 1A, the anode layer 20 is in contact with the light-emitting layer 40 through the bottom of the opening 110 of the pixel definition layer 30, and a light-emitting region EA where the anode layer 20 and the light-emitting layer 40 are in direct contact is formed, that is, the region where the cathode layer 60 and the anode layer 20 directly face each other via the light-emitting layer 40 forms the light-emitting region EA. Therefore, when a driving voltage is applied between the cathode layer 60 and the anode layer 20, a driving electrical current flows through the portion of the light-emitting layer 40 in the light-emitting region EA, thereby driving the light-emitting layer 40 to emit light.

In the example shown in FIG. 1A, the anode layer 20 is partially located under the pixel definition layer 30 (i.e., on the side facing toward the substrate 10) and partially exposed through the opening 110 of the pixel definition layer 30. However, embodiments of the present disclosure are not limited to the above structure. For example, the anode layer 20 may be completely located within the opening 110 of the pixel definition layer 30 and exposed, and, in this case, the pixel definition layer 30 does not cover the anode layer 20.

As shown in FIG. 1A, the opening 110 of the pixel definition layer 30 is formed in an inverted-cone shape, and the aperture on the side away from the substrate 10 is larger than that on the side near the substrate 10, so that the sidewall of the opening 110 of the pixel definition layer 30 forms an acute angle with respect to the substrate 10. Furthermore, as shown in FIG. 1B, the planar shape of the opening 110 of the pixel definition layer 30 is rectangular with four sidewalls. The reflection layer 50 is formed on the four sidewalls, thereby forming a closed ring shape. Embodiments of the present disclosure are not limited to this configuration, for example, the planar shape of the opening 110 of the pixel definition layer 30 may be any other shape, such as oval, racetrack shape, etc. The reflection layer 50 may be formed on part of the sidewalls of the opening of the pixel definition layer 30, thereby forming a non-closed shape. For example, in a case where the planar shape of the opening 110 of the pixel definition layer 30 is rectangular, the reflection layer 50 may be formed on a pair of sidewalls of the opening 110 opposite to each other.

In at least one embodiment, for example, the substrate 10 comprises an array substrate, so the display panel is an active display panel, such as an active-matrix organic light emitting diode (AMOLED) display panel. The array substrate includes a plurality of gate lines, a plurality of data lines, a power supply line, etc. The gate lines and the data lines cross each other to define a plurality of pixel units arranged in an array, and each of the pixel units includes a pixel driving circuit and a light-emitting element, and the pixel driving circuit is configured to drive the light-emitting element to emit light, according to a scanning signal provided by a corresponding gate line and a data signal provided by a corresponding data line. For example, the pixel driving circuit is a 2T1C pixel circuit, which includes two TFTs (thin-film transistors) and a storage capacitor Cs to drive the light-emitting element to emit light, and one of the two TFTs is a driving transistor and the other is a data writing transistor. For another example, on the basis of the above-mentioned 2T1C pixel driving circuit, the pixel driving circuit may further have a compensation function, which can be realized by voltage compensation, current compensation or hybrid compensation. The pixel circuit with compensation function may be, for example, a 4T1C or 4T2C pixel circuit, which is not limited in the embodiments of the present disclosure and will not be described in detail here. In an embodiment related to the array substrate, after the pixel driving circuit is formed, a flat layer is formed on the surface of the substrate to provide a flat surface, and through holes are formed in the flat layer, then the anode layer 20, the pixel definition layer 30, the light-emitting layer 40 and the cathode layer 60 are formed on the flat surface. The anode layer 20 is electrically connected with the pixel driving circuit through a through hole in the flat layer.

In another embodiment of the present disclosure, the display panel may also be a passive display panel, for example, a passive matrix organic light emitting diode (PMOLED) display panel. The substrate 10 includes a plurality of anode lines arranged in parallel, which are electrically connected with anode layers 20. Accordingly, an active device such as thin film transistor is not provided in each pixel unit of the substrate 10.

In an embodiment of the present disclosure, the substrate 10 may include a base substrate on which required circuits and structures are formed. For example, the base substrate may be a rigid substrate or a flexible substrate, the rigid substrate can be a glass substrate, a ceramic substrate, a plastic substrate, etc., and the flexible substrate can be a plastic substrate (such as a polyimide substrate), a glass substrate, etc., which is not limited by the present disclosure.

On the substrate 10, the pixel definition layer 30 is used to separate pixel units adjacent to each other in the pixel array and prevent crosstalk between adjacent pixel units. For example, the pixel definition layer 30 forms an opening for each pixel unit; or, the pixel definition layer 30 forms an opening for a plurality of pixel units, and the pixel units corresponding to the same one opening emit light of the same color, so that these pixel units can share the same light-emitting layer. For example, the materials of light-emitting layers of pixel units that emit light of different colors are different from each other.

For example, the cathode layer 60 is a common cathode layer, that is, the cathode layer 60 is shared by multiple pixel units. For example, the cathode layer 60 can be shared by multiple pixel units emitting light of the same color, or shared by multiple pixel units emitting light of different colors.

The material of the anode layer 20 can be metal, alloy, or the combination of metal, alloy and metal oxide with good conductive function, such as Ag, Au, Pd, Pt, Ag:Au (alloy of Ag and Au), Ag:Pd, Ag:Pt, Al:Au, Al:Pd, Al:Pt, Ag:Au, Ag/Pd (laminated structure of Ag and Pd), Ag/Pt, Ag/ITO and Ag/IZO Ag:Pt/ITO, Al:Au/ITO, Al:Pd/ITO, Ag:Au/ITO, Ag:Pd/IZO, Ag:Pt/IZO, Al:Au/IZO, Al:Pd/IZO, Al:Pt/IZO, Ag:Au/IZO etc., which is not limited by the present disclosure.

The material of the pixel definition layer 30 may be an inorganic insulating material or an organic insulating material, for example, the inorganic insulating material may be an oxide or nitride, such as silicon oxide, silicon nitride, silicon oxynitride, etc., and the organic insulating material may be a resin material, etc.

The material of the cathode layer 60 may be a material with low work function, such as magnesium (Mg), calcium (Ca), indium (In), lithium (Li), aluminum (Al), silver (Ag) or their alloys or fluorides, such as magnesium (Mg)-silver (Ag) alloy, lithium (Li)-fluorine compound, lithium (Li)-oxygen (O) compound, etc., which is not limited by the present disclosure.

For the OLED, the organic light-emitting material of the light-emitting layer 40 can be a fluorescent light-emitting material or a phosphorescent light-emitting material, for example, the material can be the light-emitting material obtained by doping, for example, the base light-emitting material includes any of metal complex materials, anthracene derivatives, aromatic diamine compounds, triphenylamine compounds, aromatic triamine compounds, benzidine diamine derivatives, triarylamine polymers, or derivatives containing carbazole groups, the doped fluorescent light-emitting material includes any of coumarin dye (coumarin 6, C-545T), quinacridone (DMQA), 2,5,8,11-tetra-tert-butyl perylene, 5,6,11,12-tetraphenyl-tetracene, N,N′-dimethyl quinacridone or 4-(Dinitrile methylene)-2-methyl-6-(4-dimethylamino-styrene)-4H-pyran (DCM) series, which are not limited by the present disclosure.

For the QLED, the quantum dot light-emitting material of the light-emitting layer 40 includes silicon quantum dots, germanium quantum dots, cadmium sulfide quantum dots, cadmium selenide quantum dots, cadmium telluride quantum dots, zinc selenide quantum dots, lead sulfide quantum dots, lead selenide quantum dots, indium phosphide quantum dots, indium arsenide quantum dots, etc., and the shape of the quantum dots can be spherical or spheroidal, and the particle size is between 2 nm and 20 nm, which is not limited by the present disclosure.

In various embodiments, the light-emitting layer of an OLED or QLED as a light-emitting element may be in a multi-layer structure. In addition to the film layer including the light-emitting material, the multi-layer structure also includes one or more auxiliary layers for assisting the entry of carriers (holes or electrons), such as an electron injection layer, an electron transport layer, a hole transport layer, a hole injection layer, etc., which is not limited by the present disclosure.

As shown in FIG. 1A, in the case where the light-emitting layer 40 in the light-emitting element emits light, the light ray a is emitted onto the reflection layer 50, the light ray a can be reflected back into the field of view, while the light ray b will be emitted out of the field of view, resulting in a color shift depending on viewing angle.

For example, the upper side in FIG. 1A is the light-emitting side of the display panel, so the light-emitting element of the present embodiment is of a top emission type, and the anode layer 20 itself has a reflection characteristic; or the anode layer 20 has a laminated structure, and in addition to the conduction layer in direct electrical contact with the light-emitting layer 40, the laminated structure further includes a reflection layer on the side close to the substrate 10 to reflect the light emitted by the light-emitting layer 40.

In the embodiment of the present disclosure, different requirements for viewing angles can be determined according to different use purposes of the display panel, and in the cross-sectional view shown in FIG. 1A, the length L of the reflection layer 50 on the sidewall of the opening 110 of the pixel definition layer 30 is set, thereby obtaining a corresponding display panel.

In at least one embodiment of the present disclosure, the pixel definition layer 30 may have a single-layer structure or a multi-layer structure. In a case of a single layer structure, the reflection layer 50 is formed on the sidewall of the opening 110 of the pixel definition layer 30, thereby being in direct contact with the light-emitting layer 40. In a case of a multi-layer structure, the reflection layer 50 may be formed, for example, in the sidewall of the opening of the pixel definition layer 30, thereby avoiding direct contact with the light-emitting layer 40. As shown in FIG. 1A, in one example, the pixel definition layer 30 includes a first sub-pixel definition layer 31 and a second sub-pixel definition layer 32. The first sub-pixel definition layer 31 is disposed on the substrate 10 and the anode layer 20, and includes a first opening 111 to at least partially expose the anode layer 20. The second sub-pixel definition layer 32 covers a surface of the first sub-pixel defining layer 31 and includes a second opening 112 to at least partially expose the anode layer 20. The orthographic projection of the second opening 112 on the substrate 10 is located within the orthographic projection of the first opening 111 on the substrate 10, and corresponds to the opening 110 of the pixel definition layer. In this case, the reflection layer 50 is located between a sidewall of the first opening of the first sub-pixel definition layer 31 and a sidewall of the second opening of the second sub-pixel definition layer 32, thereby being formed on the sidewall of the opening 110, so the second sub-pixel definition layer 32 provides protection for the reflection layer 50.

In other embodiments, besides the first sub-pixel definition layer 31 and the second sub-pixel definition layer 32, the pixel definition layer 30 may also include more other layer structures, which is not limited by the present disclosure.

In at least one embodiment of the present disclosure, within an appropriate range, the length L of the reflection layer 50 on the sidewall of the opening 110 of the pixel defining layer 30 is inversely proportional to the light loss rate of the display panel. The longer the length L of the reflection layer 50 on the sidewall of the opening 110 of the pixel defining layer 30, the more light emitted by the light-emitting layer 40 will be reflected back to the field of view, thus reducing the light loss of the display panel.

For example, as shown in FIG. 1A, in the case where the length of the reflection layer 50 on the sidewall of the opening 110 of the pixel definition layer 30 is L, and the height of the pixel definition layer 30 is H; among the three emitted light rays a, b and c, the ray a can be reflected in the front viewing angle by the reflection layer 50, and the ray b and the ray c may lose or deviate from the front viewing angle.

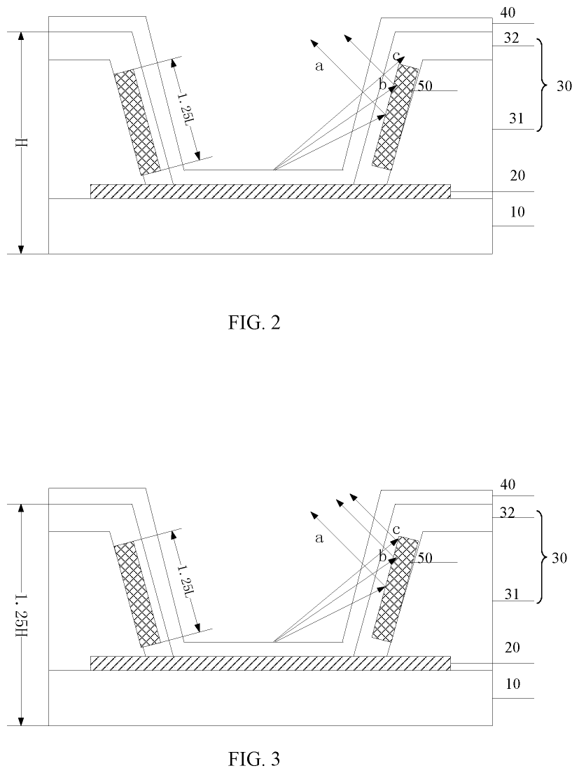

In another example as shown in FIG. 2, in the case where the length of the reflection layer 50 on the sidewall of the opening 110 of the pixel definition layer 30 can be set as n*L(n>0), for example, the length of the reflection layer 50 is set as 1.25L, and the height of the pixel definition layer 30 is H; among the three emitted light rays a, b and c, both rays a and b can be reflected in the range of front viewing angle, and the ray c may loss or deviate from the front viewing angle.

In another example as shown in FIG. 3, in the case where the length of the reflection layer 50 on the sidewall of the opening 110 of the pixel definition layer 30 can be set as 1.25L and the height of the pixel definition layer 30 is set as 1.25H; the three emitted light rays a, b and c can all be reflected in the front viewing angle.

It should be noted that the cathode layer 60 is omitted for the sake of clarity in the above-mentioned display panel of FIG. 2 and FIG. 3.

In conclusion, the luminous efficiency of the top emission organic light-emitting device can be improved by changing the coverage length and area of the highly reflective material used for the reflection layer and the height of the pixel definition layer through the process. In addition, the color shift depending on viewing angle of the organic light-emitting device can be adjusted to meet the different viewing angle requirements of the display panel.

In at least one embodiment of the present disclosure, the range of the length L of the reflection layer 50 is 1.6 μm to 2.3 μm; the width of the reflection layer 50 ranges from 0.1 μm to 1 μm, and the direction of the width is parallel to the direction of a surface of the substrate 10.

In at least one embodiment of the present disclosure, the height H of the pixel definition layer 30 ranges from 1.6 μm to 2.3 μm.

The length L and area of the reflection layer as well as the height H of the pixel definition layer can be changed by preparation processes, thus improving the luminous efficiency of the display panel. In addition, the color shift depending on viewing angle of the display panel can be adjusted to meet different viewing angle requirements of the display panel.

In an embodiment of the present disclosure, the material of the reflection layer includes at least one of Al, Cu, Ag, Al₂O₃ and ZnO.

In at least one embodiment of the present disclosure, the included angle between the sidewall of the opening 110 of the pixel definition layer 30 and the substrate 10 ranges from 60° to 80°, so the included angle α between the reflection layer 50 and the anode layer 20 ranges from 60° to 80°, which is more conducive to reflect the light emitted from the light-emitting layer 40, improving the viewing angle characteristics of the display panel.

In at least one embodiment of the present disclosure, the reflection layer 50 is disposed parallel to the sidewall of the pixel definition layer 30.

In at least one embodiment of the present disclosure, as shown in FIG. 1A, the display panel may further include a package substrate or a package layer 70; the cathode layer 60 covers a side of the light-emitting layer 40 away from the substrate 10, and the package substrate or the package layer 70 is disposed on the side of the cathode layer 60 away from the substrate 10 for packaging the display panel and providing protection for light-emitting elements and pixel driving circuits (if any) in the substrate 10. For example, the substrate 10 and the package substrate are combined with each other by a sealant (not shown) coated on the periphery to provide sealing and protection functions; the package layer is directly formed on the substrate 10 by a thin film forming method, for example, the package layer has a single-layer structure or a composite layer structure. For example, the single-layer structure includes an inorganic insulating layer or an organic insulating layer; for example, the composite layer structure includes insulating layers of different materials, for example, a multi-layer structure in which organic insulating layers and inorganic insulating layers are alternately stacked.

As described above, in the display panel provided by at least one embodiment of the present disclosure, the reflection layer is disposed on the sidewall of the opening of the pixel definition layer, so that the light emitted from the light-emitting layer of the light-emitting element formed in the opening to the sidewall of the opening of the pixel definition layer can be reflected, thus reducing the light loss. Furthermore, the display panels according to different embodiments of the present disclosure can realize display panels with different viewing angles by adjusting the lengths of reflection layers.

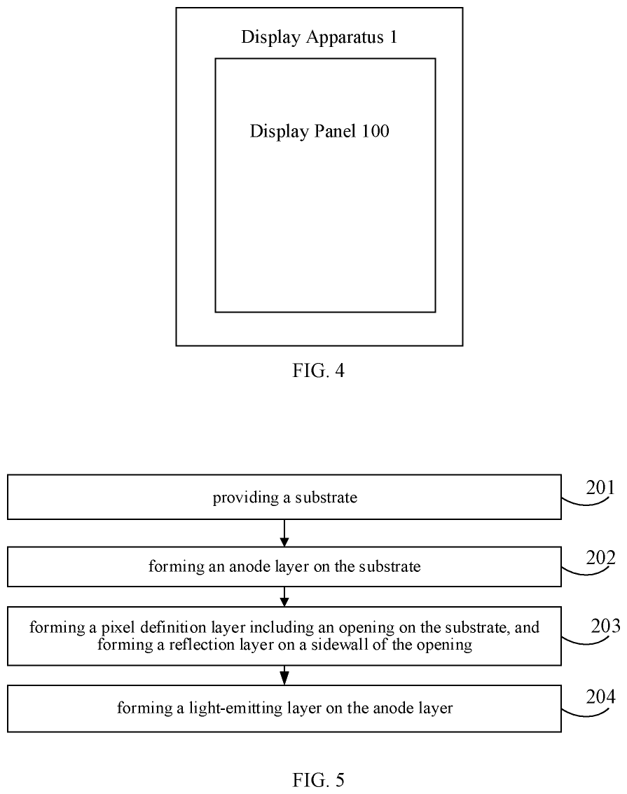

At least one embodiment of the present disclosure provides a display apparatus. As shown in FIG. 4, the display apparatus 1 includes the display panel 100 of any one of the above embodiments. For example, the display apparatus 1 may be an OLED display apparatus or a QLED display apparatus.

As understood by those skilled in the art, in addition to the above-mentioned display panel 100, the display apparatus 1 in the embodiment of the present disclosure may further include other necessary package elements and control circuits, and for example, it may also be combined with a touch panel to realize a touch display apparatus, which is not limited by the present disclosure. For example, the display apparatus can be implemented as any product or component with display function, such as a mobile phone, a tablet computer, a television, a monitor, a notebook computer, a digital photo frame, a navigator, etc. The display apparatus has all the features and advantages of the aforementioned display panel, which will not be described in detail here.

Referring to FIG. 5, an embodiment of the present disclosure provides a preparation method of a display panel. The preparation method is used to form an example of the above display panel and may include the following steps 201-204:

In step S201, providing a substrate.

For example, in the embodiment of the present disclosure, the substrate 10 may be a substrate prepared in advance, for example, the substrate may be an array substrate for an active display panel or a substrate for a passive display panel. For example, pixel driving circuits for a plurality of pixel units are formed on the array substrate.

In step S202, forming an anode layer on the substrate.

For example, an anode material layer is formed on the substrate, and then the anode material layer is patterned, for example, by a photolithography process, to form the anode layers 20 for a plurality of pixel units, for example, the anode layers 20 of these pixel units are side by side and insulated from each other. For example, the anode layers 20 of these pixel units may be electrically connected with corresponding pixel driving circuits through a plurality of through holes formed in the substrate 10 in advance.

In step S203, forming a pixel definition layer including an opening on the substrate, and forming a reflection layer on a sidewall of the opening.

For example, an insulating material layer is formed on the substrate 10 including the anode layer 20, and then the insulating material layer is patterned, for example, by a photolithography process, to form a pixel definition layer, which includes openings 110 for a plurality of pixel units, respectively. The openings 110 at least partially expose the corresponding anode layers 20; then, a reflection material layer is formed on the substrate 10, for example, the reflection material layer covers the top surface of the pixel definition layer and the openings, and then the reflection material layer is patterned, for example, by a photolithography process, to form a reflection layer on the sidewall of the respective opening of the pixel definition layer.

For example, the pixel definition layer is also at least partially formed on the surface of the anode layer 20 on the side away from the substrate 10.

In step S204, forming a light-emitting layer on the anode layer.

For example, the light-emitting layer 40 may be formed on the pixel definition layer 30 and the anode layer 20 by an evaporation method, so that the light-emitting layer 40 is continuously formed on the pixel definition layer 30 and in the opening 110 of the pixel definition layer 30, or the light-emitting layer 40 may be formed only in the opening 110 by an ink-jet printing method, so that the light-emitting layer need not be formed on the top surface of the pixel definition layer 30, but may also be formed on at least part of the sidewall of the opening 110. Then, a cathode layer 60 is formed on the light-emitting layer 40 by an evaporation method.

In at least one embodiment of the present disclosure, as shown in FIG. 1A, in the obtained display panel, in the case where the light ray a emitted from the light-emitting layer 40 is emitted onto the reflection layer 50, the light ray a can be reflected back in the field of view, while the light ray b will be emitted out of the field of view, resulting in a color shift depending on viewing angle.

In at least one embodiment of the present disclosure, for different display panels, the length L of the reflection layer on the sidewall of the opening 110 of the pixel defining layer 30 can be adjusted according to the requirements of the viewing angle, thereby obtaining display panels with different color shift depending on viewing angles.

In at least one embodiment of the present disclosure, the length L of the reflection layer 50 on the sidewall of the opening 110 of the pixel defining layer 30 is inversely proportional to the light loss rate of the display panel. In the case where the length L of the reflection layer 50 on the sidewall of the opening 110 of the pixel defining layer 30 is longer, more light will be reflected back to the field of view, thus reducing the light loss of the display panel.

In at least one embodiment of the present disclosure, the length L of the reflection layer on the sidewall of the opening 110 of the pixel defining layer 30 ranges from 1.6 μm to 2.3 μm; the width of the reflection layer 50 ranges from 0.1 μm to 1 μm, and the direction of the width is parallel to the direction of a surface of the substrate 10.

In at least one embodiment of the present disclosure, the height H of the pixel definition layer ranges from 1.6 μm to 2.3 μm.

For example, for different display panels, the lengths L and areas of the reflection layers and the heights H of the pixel definition layers can be changed by preparation processes so as to make the different display panels have different luminous efficiency. In addition, the color shift depending on viewing angle of the display panels can be adjusted to meet different viewing angle requirements of different display panels.

In at least one embodiment of the present disclosure, the material of the reflection layer includes at least one of Al, Cu, Ag, Al₂O₃ and ZnO.

In at least one embodiment of the present disclosure, the range of an included angle between the sidewall of the opening 110 of the pixel definition layer 30 and the substrate 10 is 60°-80°, so the range of the included angle α between the reflection layer and the anode layer is 60°-80°.

In at least one embodiment of the present disclosure, the reflection layer is disposed parallel to the sidewall of the pixel definition layer.

In at least one embodiment of the present disclosure, on the substrate 10, a package substrate or a package layer is also provided on the side of the cathode layer away from the substrate 10; the package substrate or the package layer is used for packaging the display panel.

In at least one embodiment of the present disclosure, the pixel definition layer 30 has a multi-layer structure, and the reflection layer is formed on the sidewall of the opening 110 of the pixel definition layer, for example, located near the light-emitting layer.

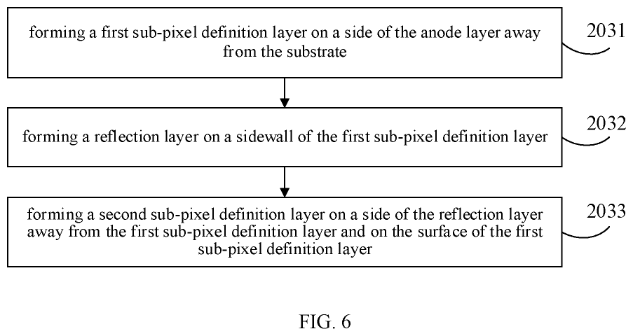

FIG. 6 illustrates an exemplary method of forming a reflection layer on a sidewall of an opening of a pixel definition layer of a multi-layer structure according to at least one embodiment of the present disclosure. The pixel definition layer 30 has a multi-layer structure, and as shown in FIG. 1A includes a first sub-pixel definition layer 31 and a second sub-pixel definition layer 32. The preparation process of this exemplary method includes the following steps 2031 to 2033.

In step 2031, forming a first sub-pixel definition layer on a side of the anode layer away from the substrate.

For example, a first insulating material layer is formed on the substrate 10 including the anode layer 20, and then the first insulating material layer is patterned by, for example, a photolithography process to form a first sub-pixel definition layer 31, and the first sub-pixel definition layer 31 includes first openings used for a plurality of pixel units, respectively.

In step 2032, forming a reflection layer on a sidewall of the first sub-pixel definition layer.

For example, a reflection material layer is deposited on the surface of the first sub-pixel definition layer 31 and in the opening by a sputtering deposition method, and the material of the reflection material layer can be any one of Al, Cu, Ag, Al₂O₃ and ZnO. The reflection material layer is patterned, for example, by photolithography, and a reflection layer 50 is formed on the sidewall of the first opening of the first sub-pixel definition layer.

In step 2033, forming a second sub-pixel definition layer on a side of the reflection layer away from the first sub-pixel definition layer and on the surface of the first sub-pixel definition layer.

For example, a second insulating material layer is formed on the substrate 10 including the first sub-pixel definition layer 31 and the reflection layer 50, and then the second insulating material layer is patterned, for example, by photolithography to form the second sub-pixel definition layer 32; the second sub-pixel definition layer 32 is laminated on the first sub-pixel definition layer 31 and covers the reflection layer 50. The second sub-pixel definition layer 32 includes second openings for a plurality of pixel units respectively, and a second opening in the second sub-pixel definition layer overlap with the a first opening in the first sub-pixel defining layer in a direction perpendicular to the substrate 10 and exposes a corresponding anode layer 20, so that the light-emitting layer 40 formed on the second sub-pixel definition layer 32 can be electrically contacted with the anode layer 20. In this example, the second opening in the second sub-pixel definition layer corresponds to the opening of the pixel definition layer.

In the preparation method of the above embodiments of the present disclosure, the materials of the anode layer, the light-emitting layer, the pixel definition layer, the cathode layer, etc. may be the same as those described above, which will not be repeated here.

In a preparation method of a display panel provided by at least one embodiment of the present disclosure, by providing a reflection layer on the sidewall of an opening of a pixel definition layer on a substrate, so that the light emitted from the light-emitting layer of the light-emitting element formed in the opening to the sidewall of the opening of the pixel definition layer can be reflected, thus reducing the light loss. Furthermore, at least one embodiment of the present disclosure can realize display panels with different viewing angles by adjusting the length of the reflection layer.

The above is only an exemplary embodiment of the present disclosure, and is not intended to limit the protection scope of the present disclosure, which is determined by the appended claims.

1. A display panel, comprising:
a substrate;
an anode layer on the substrate;
a pixel definition layer on the substrate, wherein the pixel definition layer comprises an opening to at least partially expose the anode layer;
a light-emitting layer in the opening of the pixel definition layer and on the anode layer; and
a reflection layer on a sidewall of the opening of the pixel definition layer to reflect light emitted from the light-emitting layer.

2. The display panel according to claim 1, wherein the pixel definition layer includes a first sub-pixel definition layer and a second sub-pixel definition layer;
the first sub-pixel definition layer is on the substrate and comprises a first opening at least partially exposing the anode layer,
the second sub-pixel definition layer is on a side of the first sub-pixel definition layer away from the substrate and comprises a second opening at least partially exposing the anode layer;
an orthographic projection of the second opening on the substrate is located within an orthographic projection of the first opening on the substrate, and corresponds to the opening of the pixel definition layer;
the reflection layer is located between a sidewall of the first opening of the first sub-pixel definition layer and a sidewall of the second opening of the second sub-pixel definition layer.

3. The display panel according to claim 1, wherein the light-emitting layer is on the pixel definition layer and the anode layer.

4. The display panel according to claim 1, wherein the pixel definition layer is also at least partially formed on a surface of the anode layer on a side away from the substrate.

5. The display panel according to claim 1, wherein a length of the reflection layer ranges from 1.6 μm to 2.3 μm; a width of the reflection layer ranges from 0.1 μm to 1 μm, and a direction of the width is parallel to a direction of the substrate.

6. The display panel according to claim 1, wherein a material of the reflection layer comprises any one selected from the group consisting of Al, Cu, Ag, Al₂O₃ and ZnO.

7. The display panel according to claim 1, wherein an included angle between the reflection layer and the anode layer ranges from 60° to 80°.

8. The display panel according to claim 1, further comprising a cathode layer, wherein the cathode layer is on a side of the light-emitting layer away from the substrate.

9. The display panel according to claim 8, further comprising a package substrate or a package layer, wherein the package substrate or the package layer is on a side of the cathode layer away from the substrate.

10. A display apparatus, comprising a display panel, which comprises:
a substrate,
an anode layer on the substrate;
a pixel definition layer on the substrate, wherein the pixel definition layer comprises an opening to at least partially expose the anode layer;
the light-emitting layer in the opening of the pixel definition layer and on the anode layer; and
a reflection layer on a sidewall of the opening of the pixel definition layer to reflect light emitted from the light-emitting layer.

11. A preparation method of a display panel, comprising:
providing a substrate;
forming an anode layer on the substrate;
forming a pixel definition layer on the substrate, wherein the pixel definition layer comprises an opening to at least partially expose the anode layer;
forming a reflection layer on a sidewall of the opening of the pixel definition layer; and
forming a light-emitting layer in the opening of the pixel definition layer and on the anode layer.

12. The preparation method according to claim 11, wherein the forming the pixel definition layer on the substrate, comprises:
forming a first sub-pixel definition layer on the substrate, wherein the first sub-pixel definition layer comprises a first opening at least partially exposing the anode layer; and
forming a second sub-pixel definition layer on a side of the first sub-pixel definition layer away from the substrate,
wherein the second sub-pixel definition layer comprises a second opening at least partially exposing the anode layer, and a orthographic projection of the second opening on the substrate is located within a orthographic projection of the first opening on the substrate and corresponds to the opening of the pixel definition layer.

13. The preparation method according to claim 12, wherein the forming the reflection layer on the sidewall of the opening of the pixel definition layer, comprises:
forming the reflection layer on a sidewall of the first opening of the first sub-pixel definition layer, wherein the reflection layer is located between the sidewall of the first opening of the first sub-pixel definition layer and a sidewall of the second opening of the second sub-pixel definition layer.

14. The preparation method of the display panel according to claim 11, wherein the light-emitting layer is on the pixel definition layer and the anode layer.

15. The preparation method according to claim 11, wherein the pixel definition layer is also at least partially formed on a surface of the anode layer on a side away from the substrate.

16. The preparation method according to claim 11, wherein a length of the reflection layer ranges from 1.6 μm to 2.3 μm; a width of the reflection layer ranges from 0.1 μm to 1 μm, and a direction of the width is parallel to a direction of the substrate.

17. The preparation method according to claim 11, wherein a material of the reflection layer comprises any one selected from the group consisting of Al, Cu, Ag, Al₂O₃ and ZnO.

18. The preparation method according to claim 11, wherein an included angle between the reflection layer and the anode layer ranges from 60° to 80°.

19. The preparation method according to claim 11, further comprising:
forming a cathode layer on a side of the light-emitting layer away from the substrate.

20. The preparation method according to claim 19, further comprising:
providing a package substrate or a package layer on a side of the cathode layer away from the substrate.
